(19) United States
(12) Patent Application Publication
(10) Pub. No.: US 2017/0160325 A1
(43) Pub. Date: Jun. 8, 2017

(54) ION CONCENTRATION SENSOR AND ION CONCENTRATION MEASUREMENT METHOD

(71) Applicant: Sharp Kabushiki Kaisha, Sakai City (JP)

(72) Inventors: Shinobu YAMAZAKI, Sakai City (JP); Yukio TAMAI, Sakai City (JP); Yuki EDO, Sakai City (JP)

(21) Appl. No.: 15/361,611

(22) Filed: Nov. 28, 2016

(30) Foreign Application Priority Data
Dec. 3, 2015 (JP) 2015-236962

(51) Int. Cl. G01R 29/24; H01L 27/148

(52) U.S. Cl. CPC G01R 29/24; H01L 27/14806

(57) ABSTRACT

An ion sensor includes a sensing section that accumulates signal charges, an ion-sensitive membrane that changes the amount of signal charges which can be accumulated in the sensing section, a vertical transfer section that reads and transfers the signal charges, a reference electrode that defines a reference potential in order to determine a potential of the measurement target, and a voltage control section that changes a reference electrode voltage in association with a drive voltage for operating the ion sensor.

### BACKGROUND

1. Field

The present disclosure relates to an ion concentration sensor which measures concentration of ions included in a measurement target, and an ion concentration measurement method using the ion concentration sensor.

2. Description of the Related Art

As an ion concentration sensor that measures ion concentration of a solution, an ion concentration sensor that accumulates charged particles in a sensing section whose potential changes according to the ion concentration, and that detects the amount of charges of the charged particles is well known in the related art. In the ion concentration sensor, the charges accumulated in the sensing section are transferred to a floating diffusion section and are detected. However, in the ion concentration sensor, if the charges are not transferred normally from the sensing section to the floating diffusion section, a problem may occur in that sensitivity of the ion concentration sensor is degraded.

International Publication No. WO2006/095903 (published in Sep. 14, 2006) describes a sensor in which; an elimination well is provided consecutively to a sensing section in order to suppress degradation of a sensitivity, which is caused by transfer of charges remaining in the sensing section due to a “potential bump (barrier)” to a floating diffusion section; and the charges remaining in the sensing section are temporarily put into the elimination well.

However, the degradation of the sensitivity of the ion concentration sensor is not caused by only the above-described “potential bump”. For example, in a case where a potential of the sensing section is deep, there is a case where a part of charges accumulated in the sensing section is not transferred to the floating diffusion section, and thus degradation of the sensitivity of the ion concentration sensor occurs. International Publication No. WO2006/095903 does not describe the degradation of sensitivity due to the depth of the potential of the sensing section.

### SUMMARY

It is desirable to suppress degradation of a sensitivity of an ion concentration sensor.

According to an aspect of the disclosure, there is provided an ion concentration sensor including: a sensing section that accumulates signal charges; an ion-sensitive membrane that changes the amount of signal charges which can be accumulated in the sensing section according to an ion concentration of a measurement target; a charge transfer section that reads and transfers the signal charges which are accumulated in the sensing section according to the ion concentration; a reference electrode that defines a potential which is a reference used to determine a potential of the measurement target; and a voltage control section that can change a reference electrode voltage, which is applied to the reference electrode, in association with a drive voltage which is input to operate the ion concentration sensor.

### BRIEF DESCRIPTION OF THE DRAWINGS

FIG. 1A is an enlarged plan view illustrating a part of an ion sensor according to first to fifth embodiments of the present disclosure, FIG. 1B is a sectional view taken along a line IB-IB in the plan view of FIG. 1A, and FIG. 1C is a sectional view taken along a line IC-IC in the plan view of FIG. 1A;

FIG. 2 is a plan view illustrating the configuration of the ion sensors according to a first embodiment and a second embodiment of the present disclosure;

FIG. 3 is a timing chart illustrating a relationship between a voltage applied to a first gate electrode, and a reference electrode voltage;

FIGS. 4A to 4E are graphs illustrating states of signal charges of a sensing section and a vertical transfer section at respective time t1 to t5 illustrated in FIG. 3;

FIG. 5A is a graph illustrating a relationship of output of an output transistor and the reference electrode voltage in an ion sensor according to the embodiment and a relationship of those in an ion sensor according to a comparative example, and FIG. 5B is a graph illustrating inclinations (sensitivities of the ion sensors) of the outputs of the output transistors for the reference electrode voltage between respective data points illustrated in FIG. 5A;

FIG. 6 is a sectional view illustrating the ion sensor according to the second embodiment;

FIG. 7 is a sectional view illustrating a part of the ion sensor according to the second embodiment;

FIG. 8A illustrates a concentration profile of a dopant in a line VIIIA-VIIIA of FIG. 7, and FIG. 8B illustrates a concentration profile of the dopant in a line VIIIB-VIIIB of FIG. 7;

FIG. 9 is a timing chart illustrating a relationship between a voltage which is applied to a first gate, a reference electrode voltage, and a voltage which is applied to an N-type substrate;

FIGS. 10A to 10E are graphs illustrating states of charges of a sensing section and a vertical transfer section at respective time t1 to t5 illustrated in FIG. 9.

FIG. 11A is a graph illustrating a relationship of output of an output transistor and the reference electrode voltage in an ion sensor according to the embodiment and a relationship of those in an ion sensor according to a comparative example, and FIG. 11B is a graph illustrating inclinations (sensitivities of the ion sensors) of the outputs of the output transistors for the reference electrode voltage between respective data points illustrated in FIG. 11A;

FIG. 12A is a schematic view illustrating a position of the reference electrode in the ion sensor according to the first embodiment, and FIG. 12B is a schematic view illustrating a position of the reference electrode in the ion sensor according to a third embodiment;

FIG. 13 is a flowchart illustrating a process of an ion concentration measurement according to a fourth embodiment;

FIG. 14A is a graph illustrating a pH characteristic curve which is a curve indicative of a relationship between the reference electrode voltage and the output of the output transistor, and FIG. 14B is a graph illustrating a reference electrode voltage determination method;

FIG. 15 is a timing chart illustrating a relationship between the voltage applied to the first gate electrode and the reference electrode voltage in each step illustrated in FIG. 13;

FIG. 16 is a view illustrating an outline of a pH value measurement method according to a fifth embodiment;

FIG. 17 is a timing chart of the pH value measurement according to the fifth embodiment; and

FIG. 18 is a graph illustrating a relationship between the reference electrode voltage and the output of the output transistor.

### DESCRIPTION OF THE EMBODIMENTS

### First Embodiment

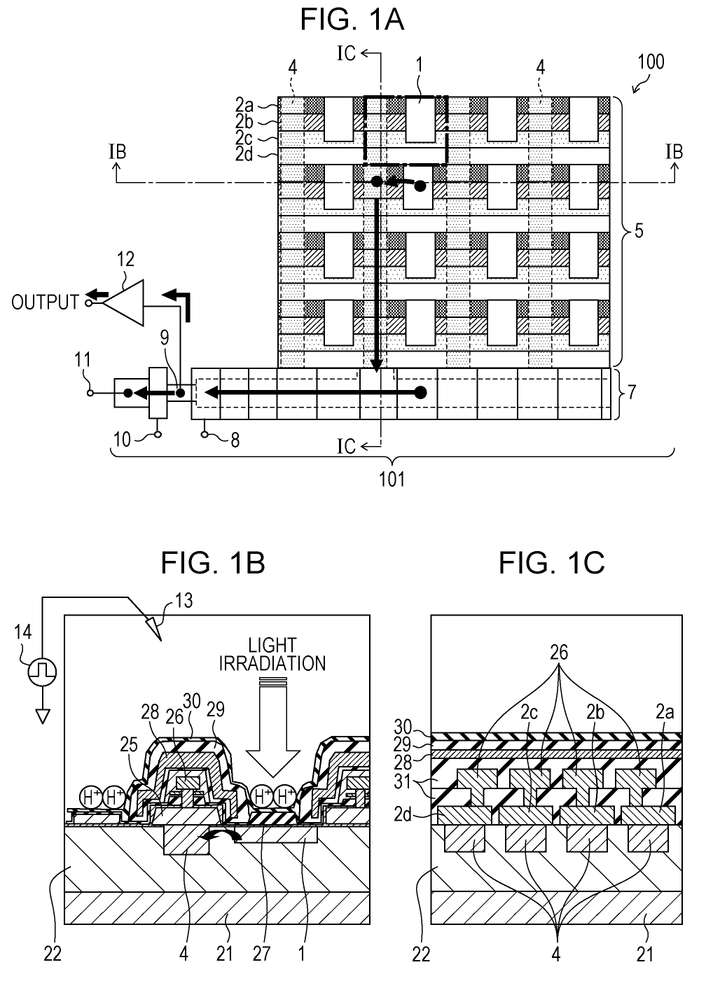

Hereinafter, an embodiment of the present disclosure will be described with reference to FIGS. 1A to 5B as below.

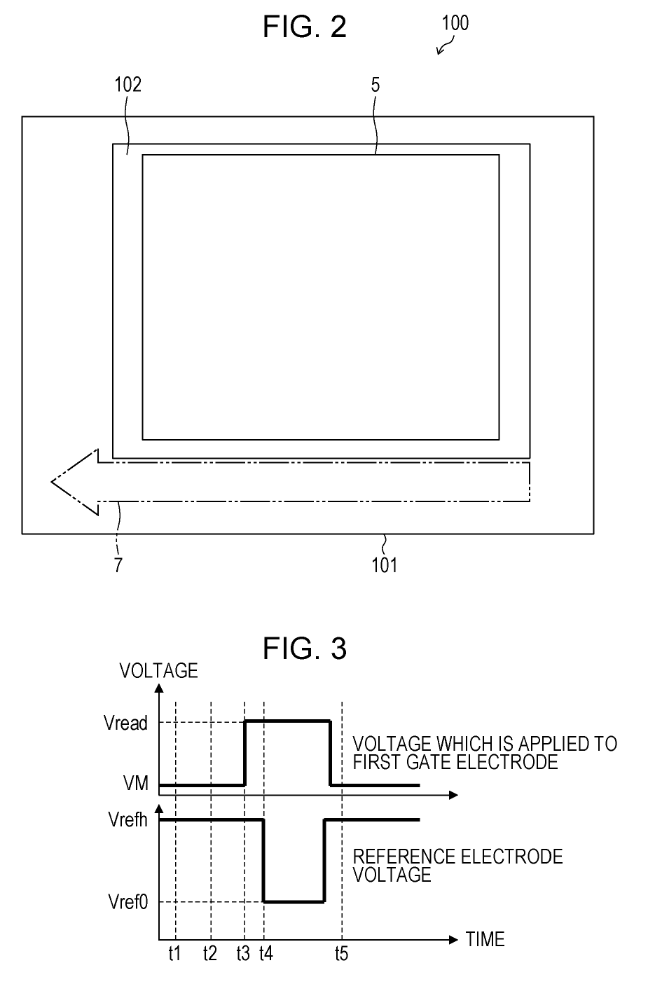

FIG. 1A is an enlarged plan view illustrating a part of an ion sensor 100 (ion concentration sensor) according to a first embodiment of the present disclosure. FIG. 1B is a sectional view taken along a line IB-IB in the plan view of FIG. 1A, and FIG. 1C is a sectional view taken along a line IC-IC in the plan view of FIG. 1A. FIG. 2 is a plan view illustrating the configuration of ion sensors according to the first embodiment and a second embodiment.

As illustrated in FIG. 2, an ion sensor 100 according to the embodiment includes a measurement area 5, a non-light receiving area 101, and an optical black 102. The ion sensor 100 is a photodiode-type ion concentration sensor using a charge coupled device (CCD) image sensor.

The measurement area 5 is formed to have a recess, and a plurality of sensing structures are disposed in a matrix shape at the bottom of the recess. A solution, which is a target (measurement target) whose ion concentration is measured, is injected into the measurement area 5. The optical black 102 is a black pixel part which is formed around the measurement area 5, and is not used to measure a hydrogen ion concentration.

The non-light receiving area 101 is further formed around the optical black 102, and is a part which does not contribute to receiving light. The non-light receiving area 101 includes a horizontal transfer section 7 or the like which will be described later.

As illustrated in FIG. 1A, the ion sensor 100 includes (i) a sensing section 1, a first gate electrode 2a, a second gate electrode 2b, a third gate electrode 2c, a fourth gate electrode 2d, and a vertical transfer section 4, which are formed in the measurement area 5, (ii) the horizontal transfer section 7, an output gate 8, a floating diffusion section 9, a reset gate 10, a reset drain 11, and an output transistor 12, which are formed in the non-light receiving area 101, and (iii) a reference electrode 13 and a voltage control section 14. In addition, as illustrated in FIGS. 1B and 1C, the ion sensor 100 includes an N-type substrate 21, a P-well 22, an electrode 26, an insulating film 27, a light-shielding film 28, an insulating film 29, and an ion-sensitive membrane 30.

The sensing section 1 is a photoelectric conversion section which converts received light into charges. The sensing section 1 is formed by, for example, a photodiode, and can accumulate charges which are acquired through the conversion. A plurality of sensing sections 1 are included in the ion sensor 100. The number of sensing sections 1 which are included in the ion sensor 100 is determined according to a purpose, a performance, or the like of the ion sensor 100.

The first to fourth gate electrodes 2a to 2d are electrodes that are used to transfer charges, which are read out from the sensing section 1 and transferred to the vertical transfer section 4, in a vertical direction. In addition, the first gate electrode 2a is a gate electrode that performs control such that charges accumulated in the sensing section 1 are simultaneously read. Meanwhile, the first to fourth gate electrodes 2a to 2d are formed on the vertical transfer section 4.

The vertical transfer section 4 (charge transfer section) transfers the read charges in the vertical direction according to an ON voltage which is applied to the first to fourth gate electrodes 2a to 2d. Here, the vertical direction is a direction that is perpendicular to a longitudinal direction of the horizontal transfer section 7 which will be described later. The vertical transfer section 4 is formed in such a way that a plurality of metal oxide semiconductor (MOS) capacitors are disposed to be adjacent to each other.

A cell is formed with one sensing section 1, the first to fourth gate electrodes 2a to 2d that correspond to the sensing section 1, and the vertical transfer section 4 that corresponds to the sensing section 1.

The horizontal transfer section 7 (charge transfer section) is formed to a well-known two-phase CCD structure that is used for a normal CCD image sensor, and transfers charges, which are output from the vertical transfer section 4, in a horizontal direction. Here, the horizontal direction is the longitudinal direction of the horizontal transfer section 7.

The output gate 8 is a gate circuit that outputs the charges, which are transferred from the horizontal transfer section 7, to the floating diffusion section 9, and outputs the charges only in a case where the ON voltage is applied.

The floating diffusion section 9 is a detection section that includes a capacitor which has an N-type area, and converts the amount of charges to a voltage by detecting the charges of the charged particles which are output from the output gate 8 as a voltage according to a capacitance of the capacitor.

The reset gate 10 is a part that resets a voltage for a cell, in which the floating diffusion section 9 completes output, before a voltage for a subsequent cell is output. The reset drain 11 is a part that applies a reset voltage of the floating diffusion section 9. The reset gate 10 is in an off-state in a case where the floating diffusion section 9 is detecting charges, and is in an on-state in a case where a reset operation is performed. Therefore, the floating diffusion section 9 is reset by a voltage which is applied to the reset drain 11.

The output transistor 12 functions as an amplifier whose input resistance is considerably high. Therefore, the output transistor 12 buffers and amplifies a voltage, which is output from the floating diffusion section 9, and outputs the voltage as a signal voltage.

Meanwhile, the output gate 8, the reset gate 10, the floating diffusion section 9, and the output transistor 12 form an output section. The number of the output section is not limited to one and the output section may be provided at a plurality of spots.

The reference electrode 13 gives a potential that is a reference in order to determine a potential of a solution which is a target whose ion concentration is measured. The reference electrode 13 is disposed to come into contact with the solution that is injected into the measurement area 5.

The voltage control section 14 controls a voltage (reference electrode voltage) that is applied to the reference electrode 13. The voltage control section 14 includes a driving power source that can change the reference electrode voltage through high-speed pulse driving. In addition, the voltage control section 14 can change the reference electrode voltage in association with a drive voltage that is input to operate the ion sensor 100. In a case where the reference electrode voltage increases, a potential of the sensing section 1 becomes deeper, and the upper limit of the amount of charges that are accumulated in the sensing section 1 becomes larger.

The N-type substrate 21 is a substrate provided with respective elements which form the ion sensor 100. The N-type substrate 21 is formed using an N-type semiconductor.

The P-well 22 is a P-type semiconductor layer that is laminated on the N-type substrate 21, and is a P-type diffusion area. The sensing section 1 and the vertical transfer section 4 are formed on a side of the P-well 22, which is separated from the N-type substrate 21, at intervals.

The electrode 26 is an electrode that comes into contact with a power supply line (not illustrated in the drawing). The electrode 26 is formed to be bonded to the first gate electrode 2a. The electrode 26 is formed of a high melting point metal film, such as TiN or W, or the silicide thereof. Therefore, it is possible to perform high-temperature heat treatment, and thus it is possible to suppress an interface state, thereby suppressing noise.

In addition, since a signal delay is reduced because the resistance of a high melting point metal film or the silicide thereof used for the electrode 26 is low, operation at high speed can be realized. However, since the high melting point metal film or the silicide thereof is a material that has a high light-shielding property, it is possible to avoid stray light from entering the N-type substrate 21 which causes optical noise. Meanwhile, it is preferable that electrodes other than the electrode 26 and wirings, which are included in the ion sensor 100, are formed of a material that is the same as that of the electrode 26.

A polysilicon electrode 25 is an electrode that is provided on the vertical transfer section 4. The polysilicon electrode 25 is connected to the electrode 26. The polysilicon electrode 25 may be understood as an electrode that generically indicates the first to fourth gate electrodes 2a to 2d.

The light-shielding film 28 is a light-shielding film that is formed to cover the first to fourth gate electrodes 2a to 2d and the electrode 26. The insulating film 29 is an insulating film that covers the light-shielding film 28.

The insulating film 27 is formed on the sensing section 1. The insulating film 27 suppresses occurrence of defects generated in a case where the ion-sensitive membrane 30 directly comes into contact with the sensing section 1, and avoids deterioration of properties. In addition, the insulating film 27 has a function as a waterproof film that avoids moisture entering a bottom layer part. The insulating film 27 may be, for example, a silicon oxide film.

The ion-sensitive membrane 30 has an ion sensitivity that changes potentials in the vicinity of the ion-sensitive membrane 30 in the sensing section 1 according to concentration of the ion in a case where the ion-sensitive membrane 30 comes into contact with specific ions. Therefore, the amount of signal charges, which can be accumulated in the sensing section 1, changes according to the concentration of the specific ions which come into contact with the ion-sensitive membrane 30. The ion-sensitive membrane 30 may be, for example, a silicon nitride film.

An inter-layer insulating film 31 is an insulating film that avoids the first to fourth gate electrodes 2a to 2d, the electrode 26, and the light-shielding film 28 directly coming into contact with each other.

### Reading of Signal Charges

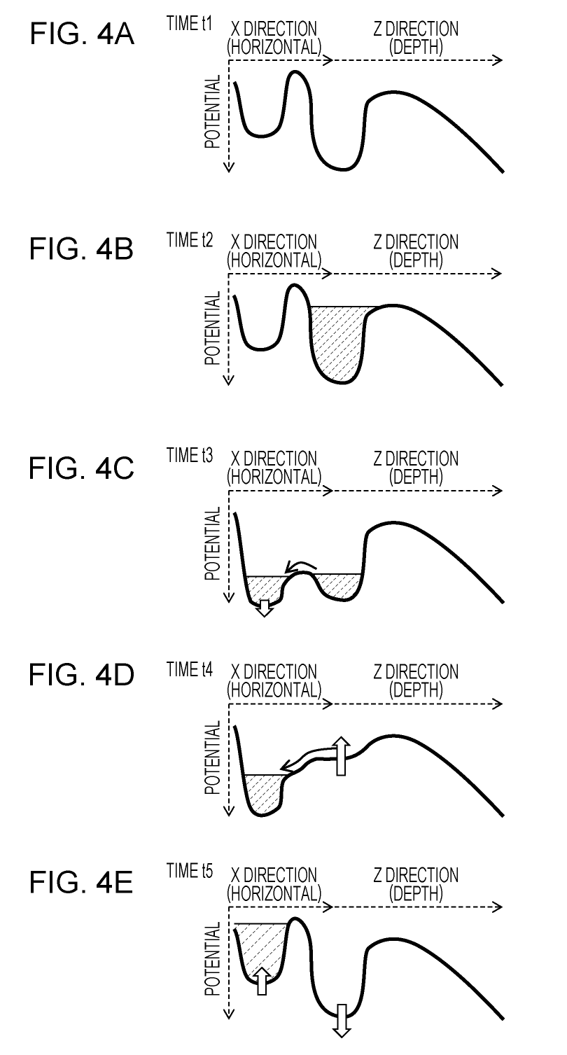

Reading of the signal charges from the sensing section 1 will be described. FIG. 3 is a timing chart illustrating a relationship between a voltage (drive voltage) applied to the first gate electrode 2a and the reference electrode voltage. FIGS. 4A to 4E are graphs illustrating states of the signal charges of the sensing section 1 and the vertical transfer section 4 at respective time t1 to t5 illustrated in FIG. 3.

In FIGS. 4A to 4E, an “X direction (horizontal)” is a direction that faces from the vertical transfer section 4 toward the sensing section 1. In addition, a “Z direction (depth)” is a direction that faces from the sensing section 1 toward the N-type substrate 21.

As illustrated in FIG. 3, at time t1, the voltage which is applied to the first gate electrode 2a is a voltage VM whose signal charges are not read from the sensing section 1. In addition, the reference electrode voltage is a voltage Vrefh in which the potential of the sensing section 1 is deep and a sensitivity becomes higher. Here, as illustrated in FIG. 4A, charges are not accumulated in either the sensing section 1 or the vertical transfer section 4.

At time t1, in a case where ion concentration measurement starts, the sensing section 1 is irradiated with light. Therefore, charges generated through photoelectric conversion are accumulated as the signal charges in the sensing section 1 which is formed by a photodiode. Thereafter, the sensing section 1 is continuously irradiated with light.

At time t2, as illustrated in FIG. 4B, the amount of charges that are accumulated in the sensing section 1 is saturated. Here, the amount of charges that are accumulated in the sensing section 1 (the amount of accumulated charges) is changed by the ion-sensitive membrane 30 according to the concentration of ions which are included in the measurement target.

At time t3, as illustrated in FIG. 3, the voltage which is applied to the first gate electrode 2a increases from VM to Vread which is an ON voltage, and reading of the signal charges, which are accumulated in the sensing section 1, starts. Therefore, as illustrated in FIG. 4C, the potential of the vertical transfer section 4 becomes deeper and a barrier between the vertical transfer section 4 and the sensing section 1 becomes lower. Therefore, the signal charges, which are accumulated in the sensing section 1, are read to the vertical transfer section 4. However, here, the potential of the sensing section 1 is deep, and thus the signal charges are read from the sensing section 1 to the vertical transfer section 4 in an incomplete state.

At time t4, as illustrated in FIG. 3, the voltage control section 14 changes the reference electrode voltage so as to be reduced from Vrefh to Vref0 in association with the increase in the voltage which is applied to the first gate electrode 2a. Therefore, as illustrated in FIG. 4D, the potential of the sensing section 1 becomes shallower. As a result, it is easy to read the signal charges from the sensing section 1 to the vertical transfer section 4, and the signal charges, which are accumulated in the sensing section 1, are sufficiently read to the vertical transfer section 4.

Meanwhile, in the timing chart illustrated in FIG. 3, time t4 is time which is later than time t3. However, time t4 may be time which is the same as time t3. That is, the voltage control section 14 reduces the reference electrode voltage in association with a timing at which the reading of the signal charges, which are accumulated in the sensing section 1, starts. However, if a timing at which the reference electrode voltage is reduced is previous to the timing at which the reading of the signal charges starts, the amount of the signal charges, which are accumulated in the sensing section 1, is reduced, and thus it is not preferable.

Thereafter, as illustrated in FIG. 3, at time t5, the voltage which is applied to the first gate electrode 2a is returned to VM, and the reading of the signal charges ends. Furthermore, the voltage control section 14 changes the reference electrode voltage such that the reference electrode voltage increases from Vref0 to Vrefh in association with a timing at which the reading of the signal charges ends and the voltage which is applied to the first gate electrode 2a is returned to VM. Therefore, as illustrated in FIG. 4E, in a state in which the signal charges, which are accumulated in the sensing section 1, are read to the vertical transfer section 4 and the signal charges do not remain in the sensing section 1, the potentials of the sensing section 1 and the vertical transfer section 4 return to the state which is illustrated in FIG. 4A.

Meanwhile, the signal charges are transferred from the vertical transfer section 4 to the floating diffusion section 9 in the same manner as in a CCD image sensor according to the related art, and thus the description thereof will not be repeated.

### Advantage of Ion Sensor 100

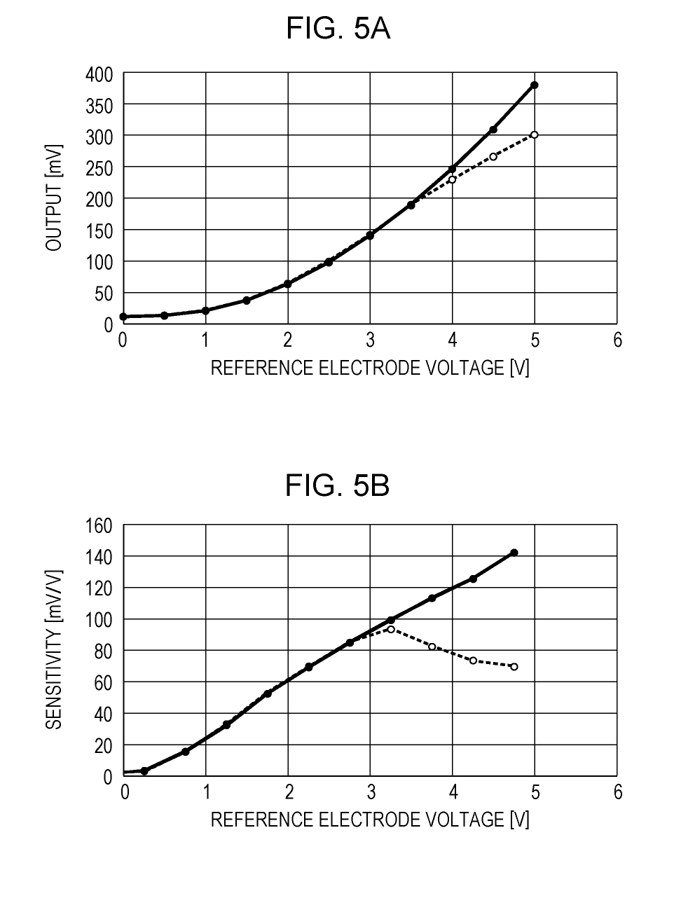

FIG. 5A is a graph illustrating a relationship of output of an output transistor 12 and the reference electrode voltage in an ion sensor 100 according to a comparative example. FIG. 5B is a graph illustrating inclinations of the outputs of the output transistors 12 for the reference electrode voltage. The inclination is obtained by using respective data points illustrated in FIG. 5A. The inclination is the rate of change in the output (sensitivities of the ion sensors). Here, the ion sensor according to the comparative example is an ion sensor in which the voltage of the reference electrode 13 is not adjusted in a case of measurement and is fixedly maintained. Meanwhile, a limit value of the rate of the change in the output, which is acquired in a case where the interval between the respective data points is reduced to the limit, is a differential coefficient of the output of the output transistor 12 for the reference electrode voltage, and is an inclination of a tangent line of the graph illustrated in FIG. 5A.

In the ion sensor according to the comparative example, as illustrated by a broken line in FIG. 5A, the increase in the output voltage (output) of the output transistor 12 is dulled with the increase in the reference electrode voltage. In addition, as illustrated by a broken line in FIG. 5B, the sensitivity of the ion sensor is degraded with the increase in the reference electrode voltage.

In contrast, in the ion sensor 100 according to the embodiment, as illustrated by a solid line in FIG. 5A, the increase in the output is not dulled even though a normal reference electrode voltage rises. In addition, as illustrated by a solid line in FIG. 5B, the sensitivity of the ion sensor 100 rises even though the reference electrode voltage rises. That is, in a case where the reference electrode voltage is caused to be high when the ion concentration is measured, it is possible to suppress the sensitivity of the ion sensor 100 from degrading.

Meanwhile, the configuration of the ion sensor 100 is not limited to the example, and an ion sensor may be provided in which the vertical transfer section 4 is separated from the sensing section 1 and the signal charges are read by lowering a barrier between the vertical transfer section 4 and the sensing section 1.

### Second Embodiment

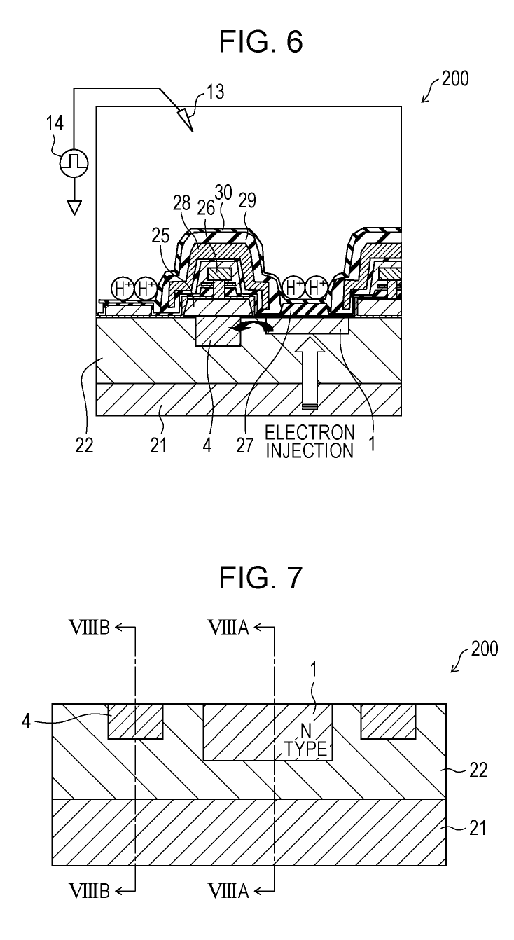

Another embodiment of the present disclosure will be described with reference to FIGS. 6 to 11B as below. In the embodiment, an ion sensor 200 in which electrons are injected from the N-type substrate 21 to the sensing section 1 will be described. Meanwhile, for convenience of explanation, the same reference symbols are attached to members which have the same functions as the members that are described in the above-described embodiment, and the description thereof will not be repeated.

FIG. 6 is a sectional view illustrating the ion sensor 200 according to the embodiment. In the ion sensor 100 according to the first embodiment, the signal charges, which are accumulated in the sensing section 1, are charges generated through photoelectric conversion. In contrast, as illustrated in FIG. 6, in the ion sensor 200 according to the embodiment, electrons, which are injected from the N-type substrate 21 to the sensing section 1, are accumulated as the signal charges.

In the embodiment, a power supply (not illustrated in the drawing), which applies a voltage in order to control the injection of the electrons from the N-type substrate 21 to the sensing section 1, is connected to the N-type substrate 21. In a case where the electrons are not injected from the N-type substrate 21 to the sensing section 1, a voltage, which is equal to or higher than a prescribed voltage (suppression voltage), is applied to the N-type substrate 21 such that electrons are not injected from the N-type substrate 21 to the sensing section 1.

In contrast, in a case where the electrons are injected from the N-type substrate 21 to the sensing section 1, a voltage which is lower than the suppression voltage is applied to the N-type substrate 21. After the electrons are completely injected to the sensing section 1, the signal charges are read from the sensing section 1, and a pulse of the reference electrode voltage is controlled in association with the reading, similarly to the ion sensor 100.

In addition, in the ion sensor 200, concentrations of dopants differ from each other between a part, in which the sensing section 1 is formed, and the other parts in the P-well 22. Therefore, charges are suppressed from being injected to the N-type areas (the vertical transfer section 4, the horizontal transfer section 7, and the like) other than the sensing section 1 which are formed in the P-well 22.

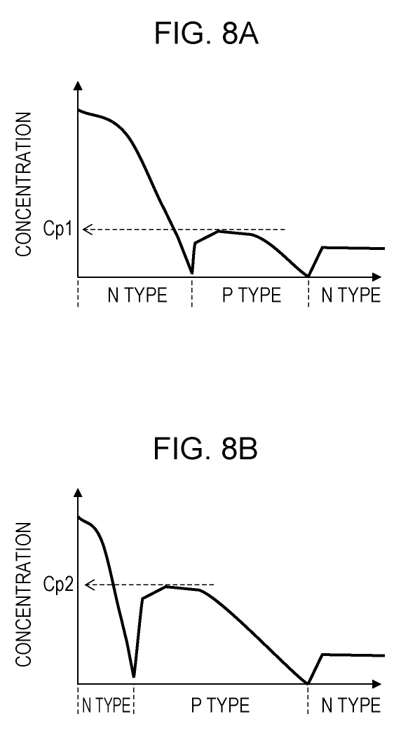

FIG. 7 is a sectional view illustrating a part of the ion sensor 200. FIG. 8A illustrates a concentration profile of a dopant in a line VIIIA-VIIIA of FIG. 7. In the concentration profile of FIG. 8A, an N-type area on the left side indicates the N-type sensing section 1, a P-type area at the center indicates the P-well 22, and an N-type area on the right side indicates the N-type substrate 21. In addition, FIG. 8B illustrates a concentration profile of a dopant in a line VIIIB-VIIIB of FIG. 7. In the concentration profile of FIG. 8B, an N-type area on the left side indicates the vertical transfer section 4, a P-type area at the center indicates the P-well 22, and an N-type area on the right side indicates the N-type substrate 21.

On the line VIIIA-VIIIA in FIG. 7, that is, in the vicinity of the sensing section 1, P-type peak concentration of the P-well 22 is Cp1 as illustrated in FIG. 8A. In contrast, on the line VIIIB-VIIIB in FIG. 7, that is, in the vicinity of the vertical transfer section 4, the P-type peak concentration of the P-well 22 is Cp2, which is higher than Cp1, as illustrated in FIG. 8B. Specifically, Cp2 is high compared to Cp1 by one digit or more. Therefore, it is easy to inject charges, which are injected from the N-type substrate 21, into the sensing section 1, and it is difficult to inject the charges into the vertical transfer section 4.

### Reading of Signal Charges

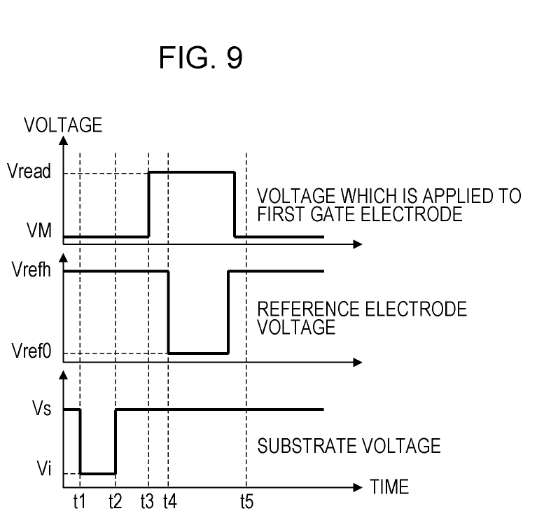

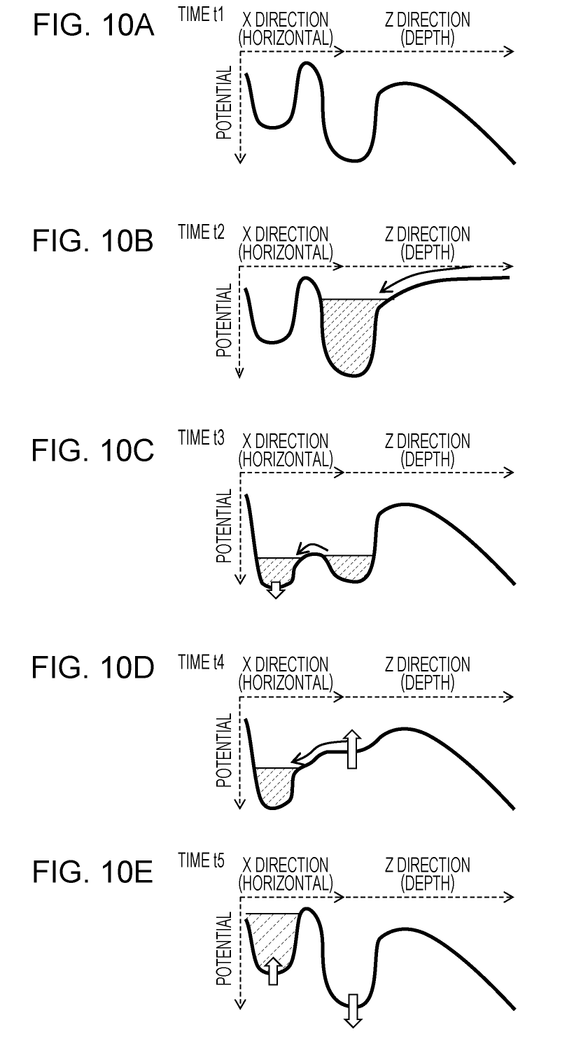

In the embodiment, reading of the signal charges from the sensing section 1 will be described. FIG. 9 is a timing chart illustrating a relationship between the voltage which is applied to a first gate electrode 2a, the reference electrode voltage, and a voltage which is applied to an N-type substrate 21. FIGS. 10A to 10E are graphs illustrating states of charges of the sensing section 1 and a vertical transfer section 4 at respective time t1 to t5 illustrated in FIG. 9. In FIGS. 10A to 10E, an “X direction (horizontal)” and a “Z direction (depth)” are defined in the same manner as in FIGS. 4A to 4E.

At time t1, as illustrated in FIG. 9, the voltage which is applied to the first gate electrode 2a is VM, a reference electrode voltage is Vrefh, and a voltage which is applied to the N-type substrate 21 is Vs. Here, as illustrated in FIG. 10A, charges are not accumulated in either the sensing section 1 or the vertical transfer section 4. In addition, here, the potential of the sensing section 1 is determined based on a pH value (hydrogen ion concentration) of the solution of the measurement target and the reference electrode voltage.

After time t1 elapses, if the voltage, which is applied to the N-type substrate 21, is degraded from the suppression voltage Vs to Vi, charges are injected from the N-type substrate 21 into the sensing section 1 and accumulated. At time t2, the signal charges, which are accumulated in the sensing section 1, are saturated, as illustrated in FIG. 10B. Thereafter, the voltage, which is applied to the N-type substrate 21, returns from Vi to Vs and is maintained as Vs until when charges are injected into the sensing section 1 again.

At time t3, as illustrated in FIG. 9, the voltage which is applied to the first gate electrode 2a increases from VM to Vread, and the reading of the signal charges, which are accumulated in the sensing section 1, starts. Therefore, as illustrated in FIG. 10C, the potential of the vertical transfer section 4 becomes deeper and a barrier between the vertical transfer section 4 and the sensing section 1 becomes lower. Therefore, the signal charges, which are accumulated in the sensing section 1, are read to the vertical transfer section 4. However, here, the potential of the sensing section 1 is deep, and thus the signal charges are read from the sensing section 1 in an incomplete state.

At time t4, as illustrated in FIG. 9, the voltage control section 14 changes the reference electrode voltage so as to be reduced from Vrefh to Vref0. Therefore, as illustrated in FIG. 10D, the potential of the sensing section 1 becomes shallower. As a result, the signal charges, which are accumulated in the sensing section 1, are sufficiently read to the vertical transfer section 4.

Thereafter, as illustrated in FIG. 9, at time t5, the voltage, which is applied to the first gate electrode 2a, returns to VM, and the reference electrode voltage returns to Vrefh. Therefore, as illustrated in FIG. 10E, in a state in which the signal charges, which are accumulated in the sensing section 1, are read to the vertical transfer section 4 and the signal charges do not remain in the sensing section 1, the potentials of the sensing section 1 and the vertical transfer section 4 return to the state illustrated in FIG. 10A.

In a case where the voltage is Vi, which is applied to the N-type substrate 21, the voltage control section 14 has to set the reference electrode voltage to Vrefh. In addition, a timing at which the voltage control section 14 sets the reference electrode voltage to Vref0 may be the same as in the first embodiment.

### Effect of Ion Sensor 200

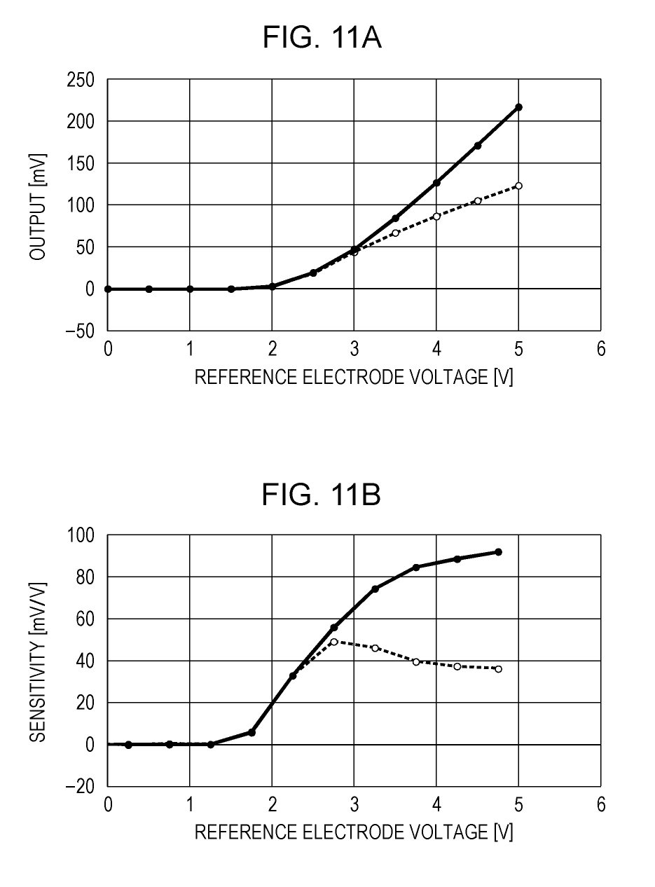

FIG. 11A is a graph illustrating a relationship of output of an output transistor 12 and the reference electrode voltage in an ion sensor 200 according to the embodiment and a relationship of those in an ion sensor according to a comparative example. FIG. 11B is a graph illustrating inclinations (sensitivities of the ion sensors) of the outputs of the output transistors 12 for a voltage which is applied to the reference electrode 13 between respective data points illustrated in FIG. 11A. Here, the ion sensor according to the comparative example is an ion sensor which does not adjust a voltage of the reference electrode 13 when measurement is performed.

In FIGS. 11A and 11B, the output and the sensitivity of the ion sensor 200 are expressed by solid lines, and the output and the sensitivity of the ion sensor according to the comparative example are expressed by broken lines. Similarly to the ion sensor 100, in the ion sensor 200, output is not dulled in accordance with the rise of the voltage which is applied to the reference electrode 13 and degradation of the sensitivity is not viewed. Furthermore, in the ion sensor 200, an illumination system which injects electrons into the sensing section 1 is not used, and thus it is possible to reduce the size of a device.

In addition, in the ion sensor 200, the sensing section 1 is not used to be irradiated with light in order to inject electrons, and thus it is possible to perform measurement in a dark state. In a case where measurement in a dark state is assumed, the light-shielding film 28 is not used.

### Third Embodiment

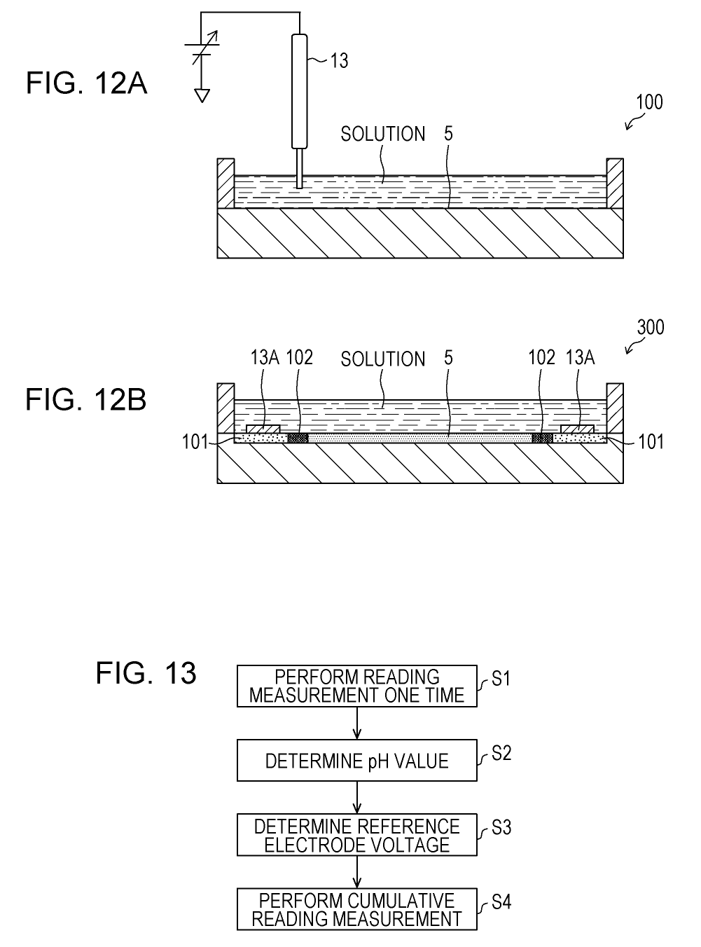

Another embodiment of the present disclosure will be described with reference to FIGS. 12A and 12B as below. An ion sensor 300 according to the embodiment includes a reference electrode 13A, which is embedded in the non-light receiving area 101, instead of the reference electrode 13. FIG. 12A is a schematic view illustrating a position of the reference electrode 13 in the ion sensor 100 according to the first embodiment. FIG. 12B is a schematic view illustrating a position of the reference electrode 13A in the ion sensor 300 according to the embodiment.

As illustrated in FIG. 12A, the reference electrode 13 of the ion sensor 100 comes into contact with a solution which is injected into the measurement area 5 from an upper side. In addition, it is the same for the ion sensor 200. In contrast, the reference electrode 13A, which is included in the ion sensor 300 according to the embodiment, comes into contact with an ion concentration measurement target and is embedded in the non-light receiving area 101 which does not contribute to receiving light, as illustrated in FIG. 12B. Specifically, the reference electrode 13A is formed in the non-light receiving area 101 using a well-known semiconductor process material. It is preferable that a metal material, which is used as the reference electrode 13A, is actually used in the semiconductor process. A detailed example of the metal material, which is used as the reference electrode 13A, includes, for example, aluminum, tungsten, platinum, copper, silver, or the like.

There is no problem in a case where a solution, which is the measurement target, comes into contact with an area, such as the non-light receiving area 101, other than the measurement area 5. Therefore, in a case where the reference electrode 13A according to the embodiment is used as the reference electrode, it is possible to reduce the size of the ion sensor 300. Meanwhile, a location in which the reference electrode 13A is provided is not particularly limited, and the reference electrode 13A may be provided on a final protective film (not illustrated in the drawing), which is provided on the outermost surface of the ion sensor 300, or in the final protective film, in addition to the above-described non-light receiving area 101.

### Fourth Embodiment

Another embodiment of the present disclosure will be described with reference to FIGS. 13 to 15 as below. It is known that a method of cumulatively reading signal charges is effective as a method of improving pH resolution by suppressing noise components in a case where a minute difference or the like of pH value or concentration of protein in a solution which is a measurement target is detected. In the embodiment, a measurement method which can cause the above-described method to be effectively functioned will be described using a fact that the voltage control section 14 can control the reference electrode voltage using a pulse.

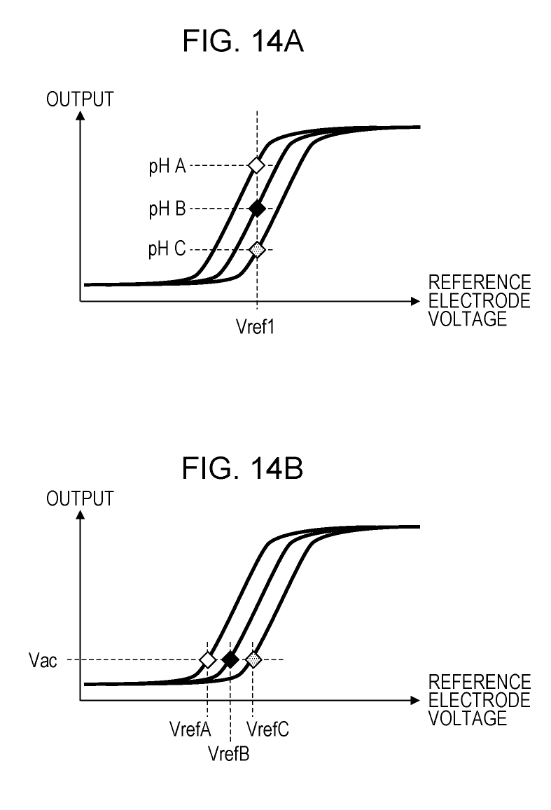

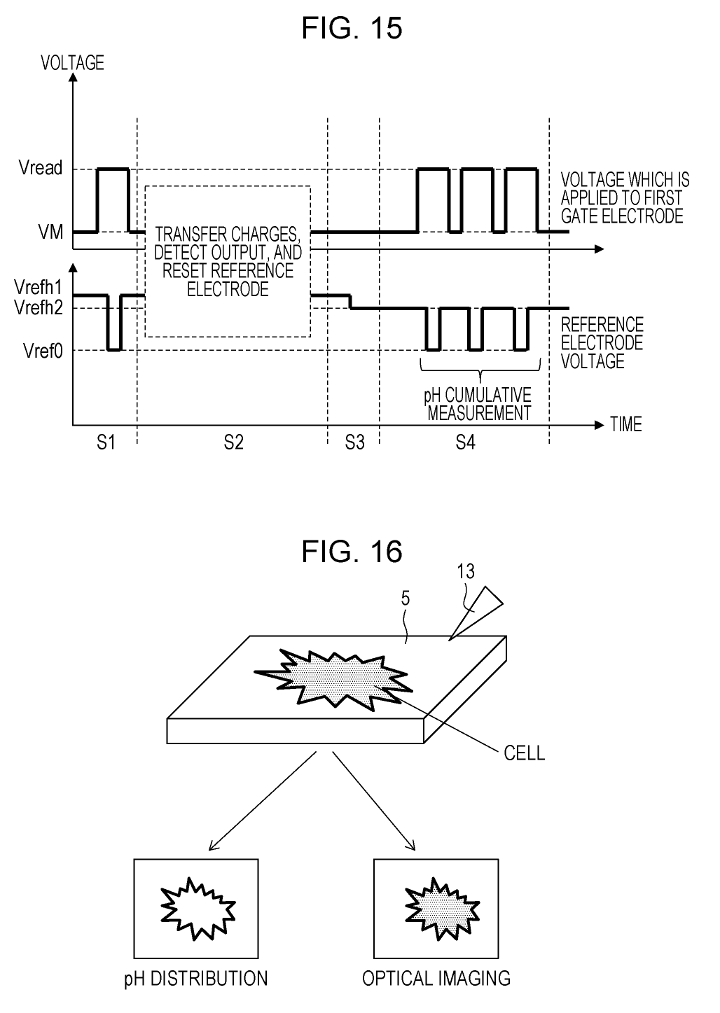

FIG. 13 is a flowchart illustrating a process of an ion concentration measurement according to the embodiment. FIG. 14A is a graph illustrating a pH characteristic curve which is a curve indicative of a relationship between the reference electrode voltage and the output of the output transistor 12 for each pH value of the solution. FIG. 14B is a graph illustrating a reference electrode voltage determination method. FIG. 15 is a timing chart illustrating a relationship between the voltage applied to the first gate electrode 2a and the reference electrode voltage in each step illustrated in FIG. 13.

Hereinafter, the ion concentration measurement method according to the embodiment will be described using the ion sensor 100. Meanwhile, the ion concentration measurement method, which will be described below, may be performed using the ion sensor 200 or 300. First, in a state in which a prescribed voltage Vref1 is applied to the reference electrode 13, reading measurement of charges, which are accumulated in the sensing section 1, is performed on the measurement target solution one time, and an output is acquired (step S1, pH value measuring step).

Subsequently, an approximate pH value of the solution is determined based on the output which is acquired in step S1, and a pH characteristic curve which is prepared in advance (step S2, pH value determining step). FIG. 14A illustrates pH characteristic curves corresponding to three types of pH values A to C. A value, at which a large difference between the outputs is generated, is selected in the respective pH values A to C as the above-described prescribed voltage Vref1, as illustrated in FIG. 14A. Meanwhile, the number of pH characteristic curves, which are prepared in advance, is not limited to three.

Subsequently, the voltage control section 14 adjusts the reference electrode voltage to a voltage, in which the number of times at which the cumulative reading measurement for the solution is performed can be maximized, based on the approximate pH value of the solution which is determined in step S2 (step S3, reference electrode voltage adjusting step). The number of times at which the cumulative reading measurement is performed is determined using the amount of charges, which are read from the sensing section 1 to the vertical transfer section 4 in one measurement, and the amount of charges which can be accumulated in the vertical transfer section 4. Specifically, the number of times at which the cumulative reading measurement is performed has to satisfy an inequality (the amount of charges which are read in one measurement)×(the number of times at which the cumulative reading measurement is performed)(the amount of charges which can be accumulated in the vertical transfer section 4). A depth of the potential of the sensing section 1 depends on the ion concentration. Therefore, as the pH value of the solution is small, that is, the hydrogen ion concentration is high, the amount of charges which are read in one measurement becomes larger.

It is preferable that the reference electrode voltage is set to a value, in which an output becomes smaller and a sensitivity for the pH value becomes larger, in order to maximize the pH resolution in the cumulative reading measurement. Such a preferable value of the reference electrode voltage is expressed as Vac in FIG. 14B. For example, in a case where the pH value of the solution is A, the reference electrode voltage, in which the output is Vac, is VrefA. Similarly, in a case where the pH value of the solution is B or C, the reference electrode voltage, in which the output is Vac, is VrefB or VrefC, respectively. The value of VrefA, VrefB, or VrefC, which corresponds to the pH value determined in step S2, is set to the value of Vrefh2 in FIG. 15.

Thereafter, the cumulative reading measurement is performed on the solution as many as a prescribed number of times using Vrefh2 which is adjusted in step S3 (step S4, cumulative reading measurement step). Therefore, it is possible to perform the cumulative reading measurement on the measurement target with a minute change in the output.

In a case where the cumulative reading measurement is performed using an ion sensor according to the related art, the reference electrode voltage has to be manually set after step S3 and before step S4 is performed. That is, it is difficult to perform steps S1 to S4 as a series of processes. In the measurement method according to the embodiment using the ion sensors 100 to 300, it is possible to perform to perform steps S1 to S4 as a series of processes, and thus it is possible to reduce time and labor which are used for measurement.

### Fifth Embodiment

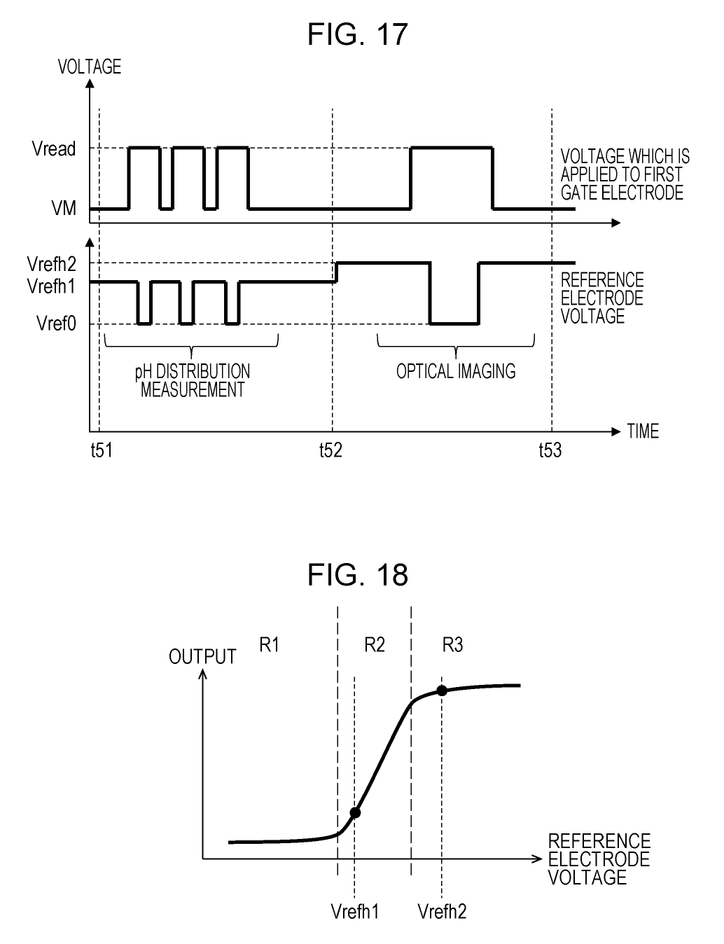

Another embodiment of the present disclosure will be described with reference to FIGS. 16 to 18 as below. In the embodiment, a measurement method for acquiring a real image (optical image) of a measurement target solution will be described. FIG. 16 is a view illustrating an outline of a pH value measurement method according to the embodiment. FIG. 17 is a timing chart of the pH value measurement according to the embodiment. FIG. 18 is a graph illustrating a method of determining the reference electrode voltage.

In a case where the ion sensors 100 to 300 are used, it is possible to measure (perform pH imaging) the distribution of the pH values, which change due to ions or the like that are secreted from a living body such as a cell, of the solution. In a case where the measurement is performed, it is desired to acquire a real image (perform optical imaging) of the measurement target in addition to the pH distribution, and to compare the pH distribution with the real image, as illustrated in FIG. 16.

As described above, the ion sensors 100 to 300 are sensors using a CCD image sensor. Therefore, according to the ion sensors 100 to 300, it is possible to perform the optical imaging in addition to the pH imaging.

However, an appropriate value of the reference electrode voltage is usually different from each other in cases where the pH imaging is performed and the optical imaging is performed. In the pH imaging, an output for one reading has to be reduced in order to perform the cumulative reading measurement. Therefore, in a case where the pH imaging is performed, it is preferable that the reference electrode voltage is reduced. In contrast, in the optical imaging, it is preferable that the output of the sensor is large, that is, the potential of the sensing section 1 is deep in order to acquire a clear real image. Therefore, in a case where the optical imaging is performed, it is preferable that the reference electrode voltage is large.

FIG. 17 is a timing chart illustrating a measurement method according to the embodiment. In FIG. 17, a period from time t51 to time t52 is a period in which the pH imaging is performed (pH imaging step). Therefore, in the period from time t51 to time t52, the reference electrode voltage is set to Vref1 that is a voltage in which it is possible to perform the cumulative reading measurement in cases other than a case in which the signal charges are read. Furthermore, in a case where the signal charges, which are accumulated in the sensing section 1, are read, the reference electrode voltage is set to Vref0 as described in the first embodiment or the like.

In contrast, a period from time t52 to time t53 is a period in which the optical imaging is performed using light (optical imaging step). Here, if the reference electrode voltage is maintained as Vref1 in the cases other than the case in which the signal charges are read, the potential of the sensing section 1 is shallow, with the result that the signal charges, which are accumulated in the sensing section 1, are easily saturated due to irradiation of light, and thus it is difficult to acquire a real image.

Here, in the period from time t52 to time t53, the reference electrode voltage is set to Vref2 in the cases other than the case in which the signal charges are read. Here, Vref2 is a value which is higher than Vref1. Therefore, the potential of the sensing section 1 becomes deeper, and an appropriate amount of signal charges is accumulated. Furthermore, in a case where the signal charges, which are accumulated in the sensing section 1, are read, the reference electrode voltage is set to Vref0 similarly to the case in which the pH imaging is performed.

FIG. 18 is a graph illustrating a relationship between the reference electrode voltage and the output of the output transistor 12. In FIG. 18, the reference electrode voltage is divided into three areas R1 to R3. In the area R1 in which the reference electrode voltage is low, the change in the output is dulled in accordance with the increase in the reference electrode voltage. In the area R2 in which the reference electrode voltage is higher than that of the area R1, the output rapidly becomes larger in accordance with the increase in the reference electrode voltage. In the area R3 in which the reference electrode voltage is higher than that of the area R2, the change in the output is dulled again in accordance with the increase in the reference electrode voltage.

The above-described value of Vref1 is the reference electrode voltage which is used to perform the cumulative reading measurement similarly to the fourth embodiment. Therefore, as illustrated in FIG. 18, it is preferable that the value of Vref1 is included in the area R2. In contrast, as illustrated in FIG. 18, it is preferable that the above-described value of Vref2 is included in the area R3 in order not to saturate the sensing section 1 with weak incident light in a case where the optical imaging is performed.

In the related art, in order to clearly perform the pH imaging and the optical imaging, respectively, individual observations have to be respectively performed. In the measurement method according to the embodiment, the reference electrode voltage is switched at high speed when the pH imaging is performed and the optical imaging is performed, and thus it is possible to perform the pH imaging and the optical imaging approximately simultaneously. For example, in a case where the pH imaging and the optical imaging are switched for every one frame, it is possible to easily compare the motion of a cell which is visualized through the pH imaging and a real image which is acquired through the optical imaging, and thus it is possible to grasp activity conditions of respective parts in the cell in detail. Meanwhile, the length of time corresponding to one frame corresponds to a period of a series of repeatedly performed operation that includes time in which charges are accumulated in the sensing section 1, time which is used to complete the reading of charges from the sensing section 1 to the vertical transfer section 4, and time which is used to transfer the charges, which are read to the vertical transfer section 4, to the output section through the horizontal transfer section 7.

### Overview

The ion concentration sensor (ion sensor 100) of a first aspect of the present disclosure includes a sensing section (1) that accumulates signal charges, an ion-sensitive membrane (30) that changes the amount of signal charges which can be accumulated in the sensing section according to ion concentration of a measurement target, a charge transfer section (vertical transfer section 4) that reads and transfers the signal charges which are accumulated in the sensing section according to the ion concentration, a reference electrode (13) that defines a potential which is a reference used to determine a potential of the measurement target, and a voltage control section (14) that can change a reference electrode voltage, which is applied to the reference electrode, in association with a drive voltage which is input to operate the ion concentration sensor.

According to the configuration, the charge transfer section reads and transfers the signal charges which are accumulated in the sensing section. The amount of the signal charges, which can be accumulated in the sensing section, is changed by the ion concentration and the potential of the measurement target which comes into contact with the ion-sensitive membrane. The reference electrode is the reference which is used to determine the potential of the measurement target. The voltage control section, which determines the potential, can change the reference electrode voltage in association with a drive voltage which is input to operate the ion concentration sensor.

Therefore, the potential of the sensing section becomes shallower in a case where the signal charges are read, and the signal charges, which are accumulated in the sensing section, are sufficiently read into the charge transfer section. Therefore, it is possible to suppress degradation of sensitivity of the ion concentration sensor.

In the ion concentration sensor of a second aspect of the present disclosure according to the first aspect, the sensing section may accumulate charges, which are generated by photoelectric conversion, as the signal charges.

According to the configuration, it is possible to accumulate the signal charges in the sensing section by irradiating the ion concentration sensor with light.

The ion concentration sensor of the third aspect of the present disclosure according to the first aspect or the second aspect may perform pH imaging and optical imaging based on the ion concentration, and may alternately perform the pH imaging and the optical imaging for every at least one frame.

According to the configuration, the pH imaging and the optical imaging are switched for every at least one frame, and thus it is possible to easily compare the motion of a cell which is visualized through the pH imaging and a real image which is acquired through the optical imaging, and thus it is possible to grasp activity conditions of respective parts in the cell in detail.

The ion concentration sensor of a fourth aspect of the present disclosure according to the first aspect, further includes a substrate (N-type substrate 21) that is provided with the sensing section, and the sensing section may accumulate charges, which are injected from the substrate, as the signal charges.

According to the configuration, it is possible to accumulate the signal charges in the sensing section by changing the potential of the substrate.

The ion concentration sensor of a fifth aspect of the present disclosure according to any one of the first to fourth aspects may further include a non-light receiving area (101) that is formed around the sensing section, is configured to come into contact with the ion concentration measurement target, and is configured not to receive light, and the reference electrode may be embedded in the non-light receiving area.

According to the configuration, it is possible to reduce the size of the ion concentration sensor.

The ion concentration sensor of a sixth aspect of the present disclosure uses an ion concentration measurement method, which is performed by the ion concentration sensor according to any one of the first to fifth aspects, the ion concentration measurement method including: determining a pH value of the measurement target; adjusting the reference electrode voltage based on the pH value by the voltage control section; and performing cumulative reading measurement on the measurement target over a predetermined number of times using the reference electrode voltage which is adjusted in the adjusting of the reference electrode voltage.

According to the configuration, it is possible to perform the pH value determining step, the reference electrode voltage adjusting step, and the cumulative reading measurement step as a series of processes. Therefore, it is possible to reduce time and labor which are used to perform the measurement.

The present disclosure is not limited to each of the above-described embodiments, and various modifications are possible within the scope of the disclosure.

Embodiments, which are acquired by appropriately combining technical units respectively described in different embodiments, are included in the technical scope of the present disclosure. Furthermore, it is possible to form new technical features by combining the technical units described in the respective embodiments.

The present disclosure contains subject matter related to that disclosed in Japanese Priority Patent Application JP 2015-236962 filed in the Japan Patent Office on Dec. 3, 2015, the entire contents of which are hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. An ion concentration sensor comprising:
a sensing section that accumulates signal charges;
an ion-sensitive membrane that changes the amount of signal charges which can be accumulated in the sensing section according to ion concentration of a measurement target;
a charge transfer section that reads and transfers the signal charges which are accumulated in the sensing section according to the ion concentration;
a reference electrode that defines a potential which is a reference used to determine a potential of the measurement target; and
a voltage control section that can change a reference electrode voltage, which is applied to the reference electrode, in association with a drive voltage which is input to operate the ion concentration sensor.

2. The ion concentration sensor according to claim 1,
wherein the sensing section accumulates charges, which are generated by photoelectric conversion, as the signal charges.

3. The ion concentration sensor according to claim 1,
wherein the ion concentration sensor can perform pH imaging and optical imaging based on the ion concentration, and alternately performs the pH imaging and the optical imaging for every at least one frame.

4. The ion concentration sensor according to claim 1, further comprising:
a substrate that is provided with the sensing section,
wherein the sensing section accumulates charges, which are injected from the substrate, as the signal charges.

5. The ion concentration sensor according to claim 1, further comprising:
a non-light receiving area that is formed around the sensing section, is configured to come into contact with the ion concentration measurement target, and is configured not to receive light,
wherein the reference electrode is embedded in the non-light receiving area.

6. An ion concentration measurement method which is performed by the ion concentration sensor according to claim 1, the ion concentration measurement method comprising:
determining a pH value of the measurement target;
adjusting the reference electrode voltage based on the pH value by the voltage control section; and
performing cumulative reading measurement on the measurement target over a predetermined number of times using the reference electrode voltage which is adjusted in the adjusting of the reference electrode voltage.
